(19) United States
(12) Patent Application Publication
(10) Pub. No.: US 2009/0284317 A1
(43) Pub. Date: Nov. 19, 2009

(54) SOURCE DRIVER OF A DISPLAY, OPERATIONAL AMPLIFIER, AND METHOD FOR CONTROLLING THE OPERATIONAL AMPLIFIER THEREOF

(76) Inventor: Ching-Chung Lee, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/121,812

(22) Filed: May 16, 2008

(51) Int. Cl. H03F 3/04

(52) U.S. Cl. 330/296; 345/204

(57) ABSTRACT

A source driver of a display includes a digital-to-analog converter, an output switch, and an operational amplifier. The operational amplifier is coupled to digital-to-analog converter for driving at least a date line of the display according to the analog pixel signal via the output switch. The operational amplifier receives a bias current, wherein the bias current is boosted only when the output switch is turned off.

### BACKGROUND OF THE INVENTION

1. Field of the Invention

The present invention relates to an operational amplifier and method, and more particularly, to an operational amplifier of a source driver and method for improving a slew-rate of the operational amplifier.

2. Description of the Prior Art

Liquid crystal display (LCD) devices are flat panel displays characterized by their thin appearance, low radiation and low power consumption. LCD devices have gradually replaced traditional cathode ray tube (CRT) displays, and have been widely applied in various electronic products such as notebook computers, personal digital assistants (PDAs), flat panel televisions, or mobile phones. An LCD device usually includes an LCD panel, a timing controller, a gate driver, and a source driver. The timing controller is used for generating image data signals, together with control signals and timing signals for driving the LCD panel. The gate driver is used for generating scan signals for turning the pixel circuits on and off, and the source driver is used for generating driving signals based on the image data signals, the control signals and the timing signals.

FIG. 1 is a diagram showing an operational amplifier 100 of a source driver according to the prior art. The operational amplifier 100 generates an output voltage Vout according to an input voltage Vin. When a switch SW is turned on by a switch control signal C_SW, the operational amplifier 100 drives an output load 1 20 of the source driver. Usually, a bias current I of the operational amplifier 100 is designed to be smaller in order to save power. However, the smaller bias current I will restrict its driving capacity and its slew-rate of the operational amplifier 100.

In order to improve the driving capacity and the slew-rate of the operational amplifier 100, the bias current I of the operational amplifier 100 is boosted when driving the output load 1 20. FIG. 2 is a diagram showing the waveforms of the switch control signal C_SW and the bias current I of the operational amplifier 100 in FIG. 1. As shown in FIG. 1 , during a period T₁, the switch SW is turned off. At this time, the bias current I of the operational amplifier 100 is maintained at a current value I₁. During a period T₂, the switch SW is turned on, and the bias current I of the operational amplifier 100 is boosted to a current value I₁′, wherein the current value I₁′ is greater than the current value I₁.

This abovementioned operation of boosting the bias current 1, however, has a drawback of causing a sudden current change, which results in glitches in the output waveforms. The glitches in the output waveforms will trigger a bouncing and cause a mura effect on the LCD device, significantly degrading its display quality.

### SUMMARY OF THE INVENTION

It is one of the objectives of the claimed invention to provide a source driver of a display and related operational amplifier and method to solve the abovementioned problems.

According to one embodiment, a source driver of a display is provided. The source driver includes a digital-to-analog converter, an output switch, and an operational amplifier. The digital-to-analog converter is used for converting a digital pixel signal into an analog pixel signal. The operational amplifier is coupled to the digital-to-analog converter for driving at least a data line of the display according to the analog pixel signal via the output switch. The operational amplifier receives a bias current, wherein the bias current is boosted only when the output switch is turned off.

According to one embodiment, an operational amplifier of a source driver is provided. The operational amplifier receives a bias current and includes a first stage, a bias current source, a second stage, and a capacitive component. The first stage receives an analog pixel signal. The bias current source provides the bias current to the first stage. The bias current source includes a first current source, a second current source, and a bias switch. The first current source provides a first bias current, and the second current source provides a second bias current via the bias switch. The bias current equals the first bias current if the bias switch is turned off, else the bias current equals a sum of the first bias current and the second bias current. The second stage is coupled to an output load of the source driver via an output switch. The capacitive component is coupled between the first stage and the second stage. The bias current is boosted only when the output switch is turned off. The bias switch is turned on when the output switch is turned off, and the bias switch is turned off before the output switch is turned on.

According to one embodiment, a method for controlling an operational amplifier of a source driver is disclosed. The method includes providing the operational amplifier having a first stage, a bias current source, a second stage, and a capacitive component coupled between the first stage and the second stage, and providing an output switch, wherein the bias current source comprises a first current source, a second current source, and a bias switch; connecting the second stage to an output load of the source driver via the output switch; and providing a bias current to the first stage, wherein the bias current equals a first bias current provided by the first current source if the bias switch is turned off, else the bias current equals a sum of the first bias current and a second bias current provided by the second current source via the bias switch. The bias current is boosted by turning on the bias switch only when the output switch is turned off.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing an operational amplifier of a source driver according to the prior art.

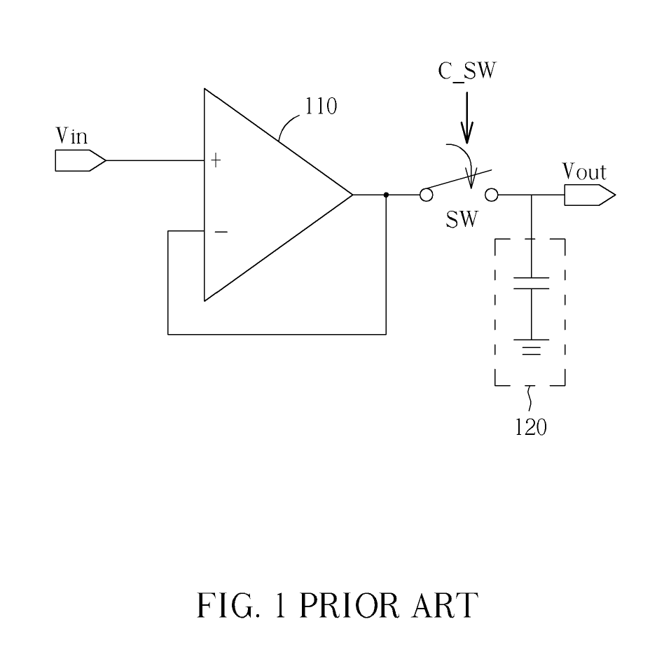

FIG. 2 is a diagram showing the waveforms of the switch control signal and the bias current of the operational amplifier in FIG. 1.

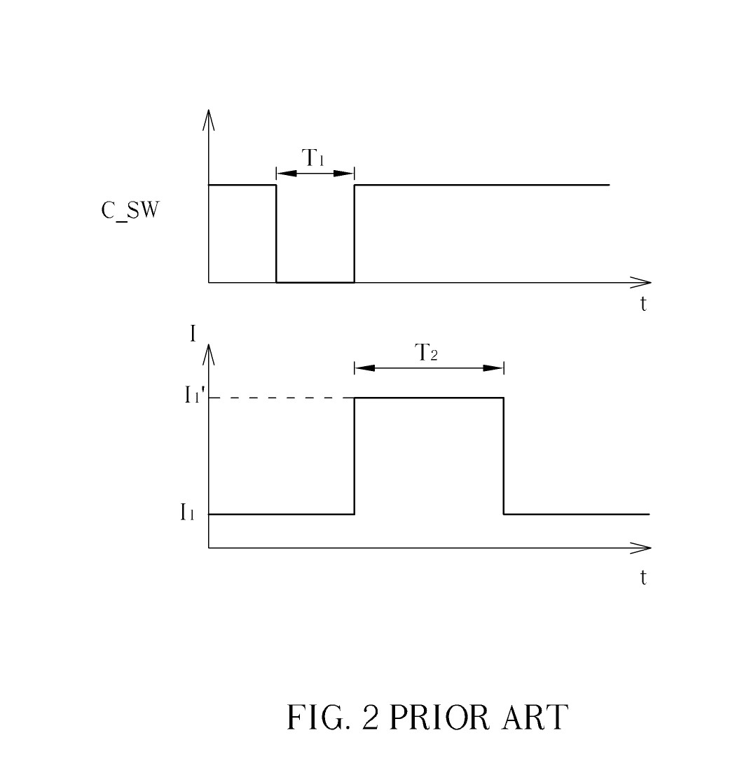

FIG. 3 is a block diagram of a source driver of a display.

FIG. 4 is a circuit diagram of the operational amplifier shown in FIG. 3.

FIG. 5 is a diagram showing the waveforms of the bias switch control signal, the output switch control signal, and the bias current of the operational amplifier in FIG. 4 according to a first embodiment of the present invention.

FIG. 6 is a diagram showing the waveforms of the bias switch control signal, the output switch control signal, and the bias current of the operational amplifier in FIG. 4 according to a second embodiment of the present invention.

FIG. 7 is a diagram showing the waveforms of the bias switch control signal, the output switch control signal, and the bias current of the operational amplifier in FIG. 4 according to a third embodiment of the present invention.

FIG. 8 is a flowchart illustrating a method for controlling an operational amplifier of a source driver according to an embodiment of the present invention.

### DETAILED DESCRIPTION

Certain terms are used throughout the following description and claims to refer to particular components. As one skilled in the art will appreciate, hardware manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ”. The terms “couple” and “coupled” are intended to mean either an indirect or a direct electrical connection. Thus, if a first device couples to a second device, that connection may be through a direct electrical connection, or through an indirect electrical connection via other devices and connections.

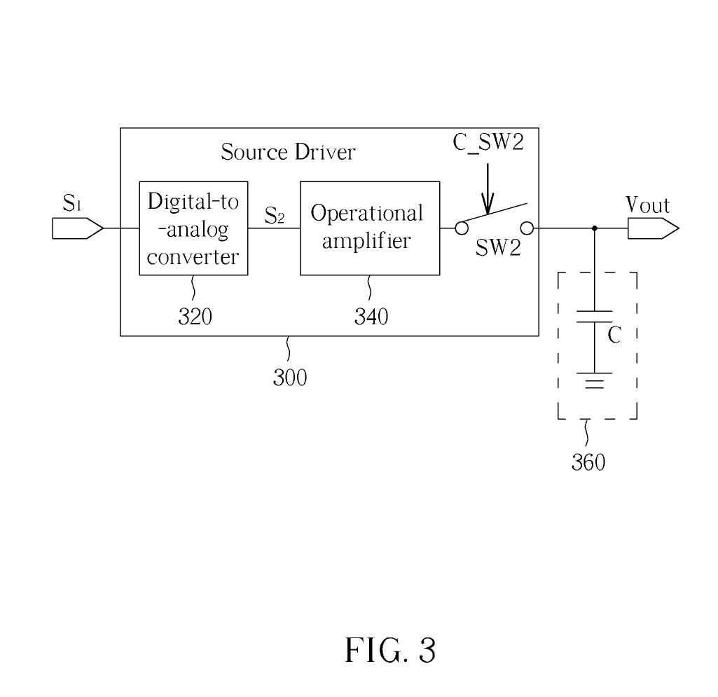

FIG. 3 is a block diagram of a source driver 300 of a display. The source driver 300 includes, but is not limited to, a digital-to-analog converter 320, an output switch SW2, and an operational amplifier 340. The digital-to-analog converter 320 converts a digital pixel signal Si into an analog pixel signal S₂. The operational amplifier 340 is coupled to the digital-to-analog converter 320 for driving at least one data line of the display according to the analog pixel signal S₂ via the output switch SW2. The data line is emulated as an output load 360, which is a capacitor C, to be driven by the operational amplifier 340.

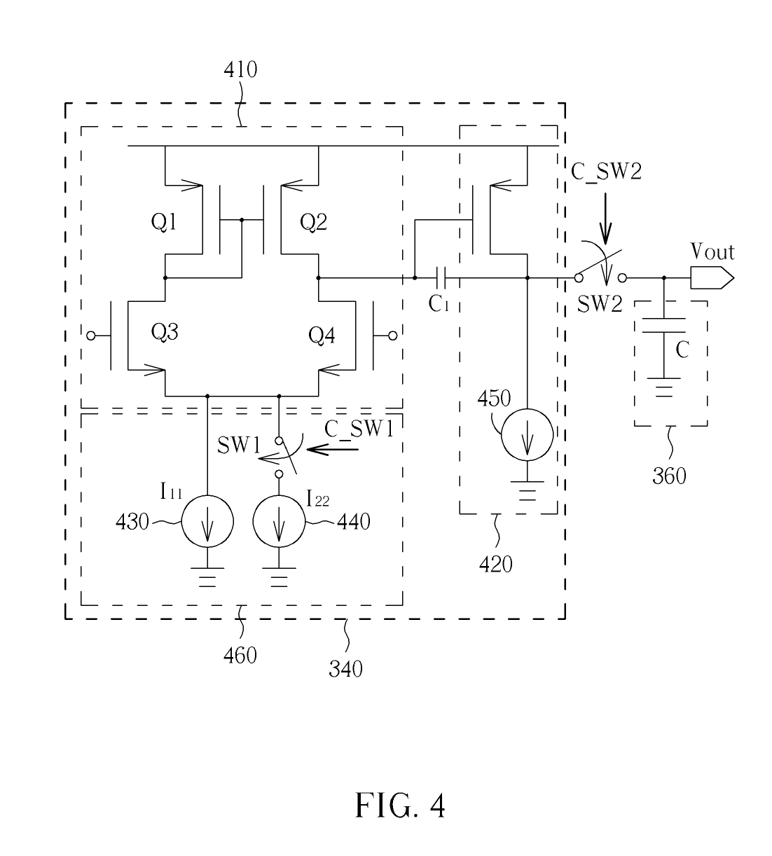

FIG. 4 is a circuit diagram of the operational amplifier 340. The operational amplifier 340 includes a first stage 410, a bias current source 460, a second stage 420, and a capacitive component C₁. The capacitive component C₁ is coupled between the first stage 410 and the second stage 420, and the output switch SW2 is coupled between the second stage 420 and the output load 360. In addition, the first stage 410 is used for receiving the analog pixel signal from the digital-to-analog converter 32, and includes four transistors Q1-Q4. The bias current source 460 is used for providing the bias current to the first stage 410, and includes a first current source 430, a second current source 440, and a bias switch SW1. The connection manner of the four transistors Q1-Q4 is shown in FIG. 4, and further description is omitted here for brevity. The first current source 430 is coupled to the transistors Q3 and Q4 for providing a first bias current I₁₁, and the second current source 440 is used for providing a second bias current I₂₂ via the bias switch SW1. The bias switch SW1 is coupled to the second current source 440 in series, and the bias switch SW1 and the second current source 440 are coupled to the first current source 430 in parallel. The bias current I equals the first bias current I₁₁ if the bias switch SW1 is turned off, else the bias current I equals a sum of the first bias current I₁₁ and the second bias current I₂₂ (i.e., I=I₁₁+I₂₂). The second stage 420 includes a fifth transistor Q5 and a third current source 450, wherein the third current source 450 is coupled to the fifth transistor Q5.

The embodiment above is presented merely for describing features of the present invention, and should not be considered to be limitations of the scope of the present invention. Certainly, people skilled in the art will readily appreciate that other designs of implementing the operational amplifier 340 are feasible.

When the output switch SW2 is turned on by an output control signal C_SW2, the operational amplifier 340 starts to drive the output load 360. When the output switch SW2 is turned off by the output control signal C_SW2, the operational amplifier 340 stops driving the output load 360. In order to achieve a goal of improving the slew-rate of the operational amplifier 340 without causing glitches in the output waveforms, a mechanism for controlling the operational amplifier 340 is disclosed in the present invention. The bias current I of the operational amplifier 340 is boosted when the output switch SW2 is turned off. In other words, the bias switch SW1 is turned on by a first control signal C_SW1 when the output switch SW2 is turned off.

Please note that, the bias switch SW1 and output switch SW2 can be implemented by a metal oxide semiconductor filed transistor (MOSFET), but can also be other types of switches. In addition, the display can be an LCD device, but is not limited to this in the present invention.

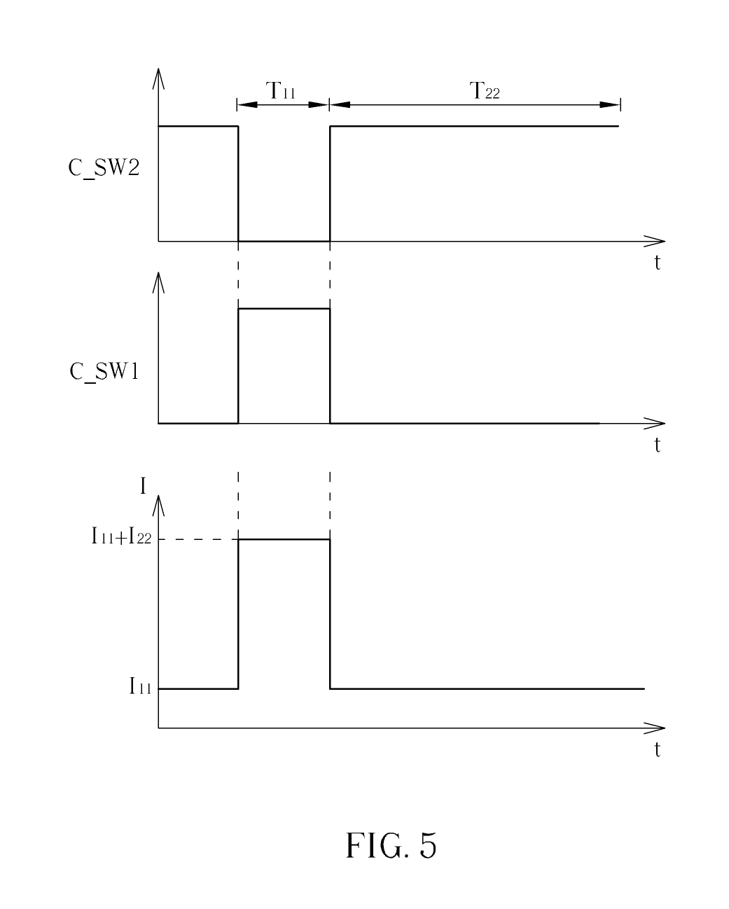

FIG. 5 is a diagram showing the waveforms of the bias switch control signal C_SW1, the output switch control signal C_SW2, and the bias current I of the operational amplifier 340 in FIG. 4 according to a first embodiment of the present invention. As shown in FIG. 5, during a period T₁₁, the output switch SW2 is turned off and the bias switch SW1 is turned on. At this time, the bias current I of the operational amplifier 340 is boosted to a current value (I₁₁+I₂₂) due to the bias switch SW1 being on. During period T₂₂, the output switch SW2 is turned on and the bias switch SW1 is turned off. At this time, the bias current I of the operational amplifier 340 is maintained at the current value I₁₁ due to the bias switch SW1 being off. Therefore, glitches resulting from a sudden current change will be alleviated by the output switch SW2. Moreover, the capacitive component C1 is charged to a target voltage when the bias switch SW1 is turned on during the period T₁₁, and thus, the slew-rate of the operational amplifier 340 will not be restricted. When the output switch SW2 is turned on during the period T₂₂, the capacitive component C1 can be maintained at a fixed value easily and has a better capacity for stabilizing voltages. Please note that, in this embodiment, a turn-on period (i.e., T₁₁) of the bias switch SW1 is equal to a turn-off period of the output switch SW2.

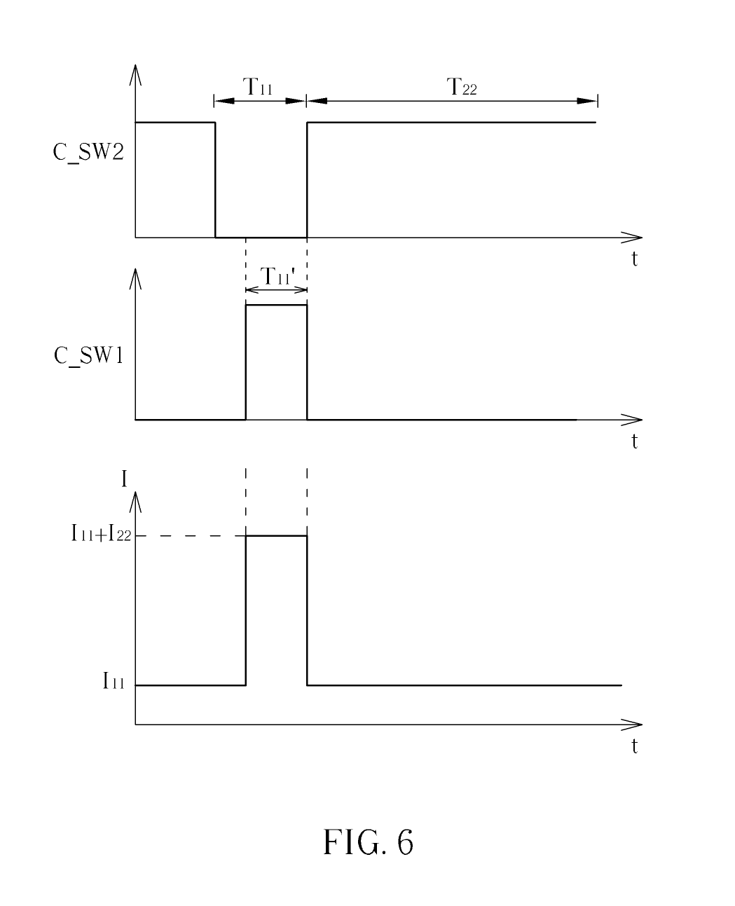

FIG. 6 is a diagram showing the waveforms of the bias switch control signal C_SW1, the output switch control signal C_SW2, and the bias current I of the operational amplifier 340 in FIG. 4 according to a second embodiment of the present invention. The waveforms in FIG. 6 are similar to those in FIG. 5, and the difference between them is that the bias switch SW1 is turned on during a period T₁₁′, which is smaller than the period T₁₁. In other words, there is a delay time (T₁₁-T₁₁′) that exists between the period T₁₁ and the period T₁₁′. Please note that, in this embodiment, a turn-on period of the bias switch SW1 is smaller than a turn-off period of the output switch SW2 (i.e., T₁₁′<T₁₁).

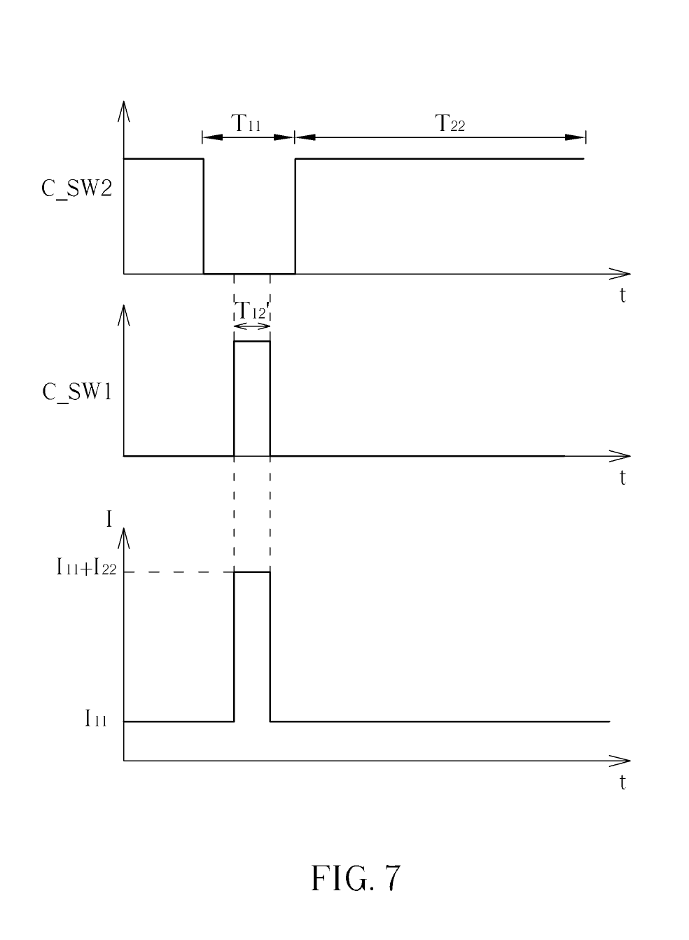

Please refer to FIG. 7. FIG. 7 is a diagram showing the waveforms of the bias switch control signal C_SW1, the output switch control signal C_SW2, and the bias current I of the operational amplifier 340 in FIG. 4 according to a third embodiment of the present invention. The waveforms in FIG. 7 are similar to those in FIG. 6, and the difference between them is that the bias switch SW1 is turned on during a period T₁₂′, which stops before the period T₁₁ ends. In other words, the bias switch SW1 is turned off before the output switch SW2 is turned on. Please note that, in this embodiment, a turn-on period of the bias switch SW1 is smaller than a turn-off period of the output switch SW2 (i.e., T₁₂′<T₁₁).

Of course, the abovementioned embodiments are merely examples for illustrating features of the present invention and should not be seen as limitations of the present invention. Those skilled in the art should appreciate that various modifications of the periods T₁₁ and T₂₂ may be made. For example, the period T₁₁ and the period T₂₂ can overlap for a small period of time, and this should also belong to the scope of the present invention.

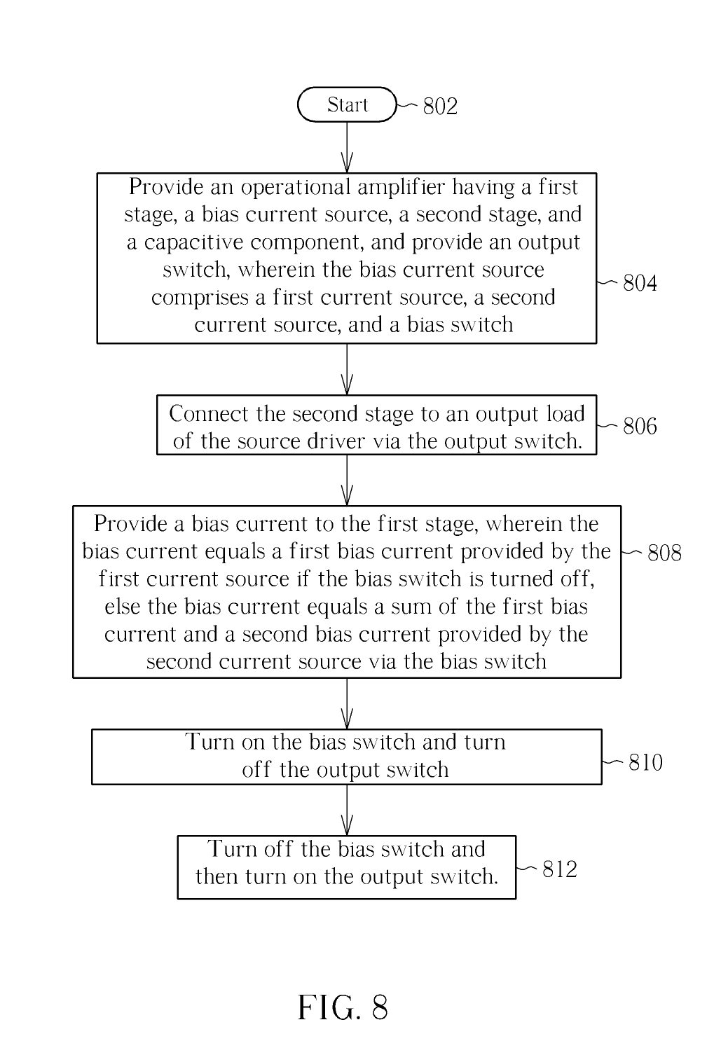

Please refer to FIG. 8. FIG. 8 is a flowchart illustrating a method for controlling an operational amplifier of a source driver according to an embodiment of the present invention. Please note that the following steps are not limited to be performed according to the exact sequence shown in FIG. 8 if a roughly identical result can be obtained. The remote live pause method includes, but is not limited to, the following steps:

Step 802: Start.

Step 804: Provide an operational amplifier having a first stage, a bias current source, a second stage, and a capacitive component coupled between the first stage and the second stage, and provide an output switch, wherein the bias current source comprises a first current source, a second current source, and a bias switch.

Step 806: Connect the second stage to an output load of the source driver via the output switch.

Step 808: Provide a bias current to the first stage, wherein the bias current equals a first bias current provided by the first current source if the bias switch is turned off, else the bias current equals a sum of the first bias current and a second bias current provided by the second current source via the bias switch.

Step 810: Boost a bias current of the operational amplifier by turning on the bias switch only when the output switch is turned off.

Step 812: Turn off the bias switch and then turn on the output switch.

In the following description, the components shown in FIG. 4 are collocated with the steps shown in FIG. 8 together with the waveforms shown in FIG. 5 and FIG. 7 for further detailed descriptions of operating manners. In Step 804-806, the operational amplifier 340 is provided. The internal architecture and the connection manner of the operational amplifier 340 have already been detailed above and further description is omitted here for brevity. In Step 808, the bias current I is provided to the first stage 410, wherein the bias current I equals a first bias current I₁₁ if the bias switch SW1 is turned off, else the bias current I equals a sum of the first bias current I₁₁ and a second bias current I₂₂. In Step 810, the bias switch SW1 is turned on only when the output switch SW2 is turn off, which is the period T₁₁ shown in FIG. 5. During this period, the bias current I is boosted. In Step 812, the bias switch SW1 is turned off when the output switch SW2 is turned on, which is the period T₂₂ shown in FIG. 5. As shown in FIG. 7, the bias switch SW1 is turned off and then the output switch SW2 is turned on.

Note that, the method shown in FIG. 8 is just a practicable embodiment, not limiting conditions of the present invention. And, the order of the steps merely represents a preferred embodiment of the method of the present invention. In other words, the illustrated order of steps can be changed based on the conditions, and is not limited to the above-mentioned order.

The abovementioned embodiments are presented merely for describing features of the present invention, and in no way should be considered to be limitations of the scope of the present invention. In summary, the present invention provides a source driver of a display and related operational amplifier and method. By boosting the current I of the operational amplifier 340 only when the output switch SW2 is turned off, a goal of improving the slew-rate of the operational amplifier 340 without causing glitches in the output waveforms can be achieved. If the operation of boosting the current I of the operational amplifier 340 is finished before starting to drive the output load 360, a mura effect will not happen on the LCD device. Moreover, the capacitive component C1 can be maintained at a fixed value easily and has a better capacity for stabilizing voltages. The mechanism for controlling the operational amplifier 340 disclosed in the present invention is especially suitable for devices with light loading, such as notebook computers, which are characterized by low power consumption. Therefore, not only can the display quality of the devices with light loading be improved, but a goal of saving power can also be achieved.

Those skilled in the art will readily observe that numerous modifications and alterations of the device and method may be made while retaining the teachings of the invention.

What is claimed is:

1. A source driver of a display, comprising:
a digital-to-analog converter, for converting a digital pixel signal into an analog pixel signal;
an output switch; and
an operational amplifier, coupled to the digital-to-analog converter, for driving at least a data line of the display according to the analog pixel signal via the output switch, the operational amplifier receiving a bias current;
wherein the bias current is boosted only when the output switch is turned off.

2. The source driver of claim 1, wherein the operational amplifier further comprises:
a first stage for receiving the analog pixel signal;
a bias current source for providing the bias current to the first stage, comprising;
a first current source, for providing a first bias current;
a bias switch; and
a second current source, for providing a second bias current via the bias switch, wherein the bias current equals the first bias current if the bias switch is turned off, else the bias current equals a sum of the first bias current and the second bias current; and
a second stage, coupled to the data line via the output switch; and
a capacitive component, coupled between the first stage and the second stage;
wherein the bias switch is turned on when the output switch is turned off.

3. The source driver of claim 2, wherein a turn-on period of the bias switch is not greater than a turn-off period of the output switch.

4. The source driver of claim 2, wherein the bias switch is turned off when the output switch is turned on.

5. The source driver of claim 2, wherein the bias switch is turned off before the output switch is turned on.

6. The source driver of claim 2, wherein the bias switch and the output switch are each a metal oxide semiconductor filed transistor (MOSFET).

7. The source driver of claim 2, wherein the first stage further comprises:
a first transistor;
a second transistor, having a first end coupled to a first end of the first transistor, a control end coupled to a control end of the first transistor, and a second end coupled to the capacitive component;
a third transistor, having a first end coupled to a second end of the first transistor and to the control ends of the first transistor and the second transistor, and a second end coupled to the first current source and the bias switch; and
a fourth transistor, having a first end coupled to the second end of the second transistor and to the capacitive component, and a second end coupled to the second end of the third transistor, the first current source, and the bias switch.

8. The source driver of claim 7, wherein the second stage comprises:
a fifth transistor, having a first end coupled to the first ends of the first transistor and the second transistor, a control end coupled to the second end of the second transistor and a first end of the capacitive component, and a second end coupled to a second end of the capacitive component; and
a third current source, coupled to the second end of the fifth transistor and the second end of the capacitive component.

9. An operational amplifier of a source driver, the operational amplifier receiving a bias current, comprising:
a first stage for receiving an analog pixel signal;
a bias current source for providing the bias current to the first stage, comprising:
a first current source, for providing a first bias current;
a bias switch; and
a second current source, for providing a second bias current via the bias switch, wherein the bias current equals the first bias current if the bias switch is turned off, else the bias current equals a sum of the first bias current and the second bias current; and
a second stage, coupled to an output load of the source driver via an output switch; and
a capacitive component, coupled between the first stage and the second stage;
wherein the bias current is boosted by turning on the bias switch only when the output switch is turned off.

10. The operational amplifier of claim 9, wherein a turn-on period of the bias switch is not greater than a turn-off period of the output switch.

11. The operational amplifier of claim 9, wherein the bias switch is turned off when the output switch is turned on.

12. The operational amplifier of claim 9, wherein the bias switch is turned off before the output switch is turned on.

13. The operational amplifier of claim 9, wherein the bias switch and the output switch are each a metal oxide semiconductor filed transistor (MOSFET).

14. The operational amplifier of claim 9, wherein the first stage further comprises:
a first transistor;
a second transistor, having a first end coupled to a first end of the first transistor, a control end coupled to a control end of the first transistor, and a second end coupled to the capacitive component;
a third transistor, having a first end coupled to a second end of the first transistor and the control ends of the first transistor and the second transistor, and a second end coupled to the first current source and the bias switch; and
a fourth transistor, having a first end coupled to the second end of the second transistor and the capacitive component, and a second end coupled to the second end of the third transistor, the first current source, and the bias switch.

15. The operational amplifier of claim 14, wherein the second stage comprises:
a fifth transistor, having a first end coupled to the first ends of the first transistor and the second transistor, a control end coupled to the second end of the second transistor and a first end of the capacitive component, and a second end coupled to a second end of the capacitive component; and
a third current source, coupled to the second end of the fifth transistor and the second end of the capacitive component.

16. A method for controlling an operational amplifier of a source driver, comprising:
providing the operational amplifier having a first stage, a bias current source, a second stage, and a capacitive component coupled between the first stage and the second stage, and providing an output switch, wherein the bias current source comprises a first current source, a second current source, and a bias switch;
connecting the second stage to an output load of the source driver via the output switch; and
providing a bias current to the first stage, wherein the bias current equals a first bias current provided by the first current source if the bias switch is turned off, else the bias current equals a sum of the first bias current and a second bias current provided by the second current source via the bias switch;
wherein the bias current is boosted by turning on the bias switch only when the output switch is turned off.

17. The method of claim 16, further comprising turning off the bias switch when the output switch is turned on.

18. The method of claim 16, further comprising turning off the bias switch before turning on the output switch.
